(19) United States
(12) Patent Application Publication
(10) Pub. No.: US 2008/0003926 A1
(43) Pub. Date: Jan. 3, 2008

(54) Method of Grinding Multilayer Body and Method of Manufacturing Solid State Image Pickup Device

(75) Inventors: Manjirou Watanabe, Kanagawa (JP); Yoshihisa Negishi, Kanagawa (JP); Hiroshi Maeda, Kanagawa (JP); Hitoshi Shimamura, Miyagi (JP)

Correspondence Address: SUGHRUE MION, PLLC, 2100 PENNSYLVANIA AVENUE, N.W., SUITE 800, WASHINGTON, DC, 20037, US

(73) Assignee: Fujifilm Corporation, Minato-ku (JP)

(21) Appl. No.: 11/663,561

(22) PCT Filed: Sep. 27, 2005
(86) PCT No.: PCT/JP05/18233

§ 371 Date: Mar. 23, 2007

(30) Foreign Application Priority Data
Sep. 29, 2004 (JP) 2004-285101
Sep. 29, 2004 (JP) 2004-285100

(51) Int. Cl. G01L 23/02; H01L 21/301

(52) U.S. Cl. 451/54; 438/460; 451/28

(57) ABSTRACT

A method of grinding a multilayer body which can prevent a substrate from being damaged by a broken piece of a planar substance, which occurs during grinding and cutting in grinding and cutting the planar substance of the multilayer substance constructed by the substrate and the planar substance which are joined with an extremely narrow gap portion therebetween is provided. A protection layer of the substrate is formed in the gap portion in advance and the substrate can be prevented from being damaged by the broken piece of the planar substance occurring by grinding, in grinding and cutting the planar substance by cutting into the gap portion with a grindstone, of the multilayer body in which the substrate and the planar substance are joined to have the gap portion therebetween.

### TECHNICAL FIELD

The present invention relates to a method of grinding a multilayer body and a method of manufacturing a solid state image pickup device, and particularly relates to a method of grinding a multilayer body and a method of manufacturing a solid state image pickup device for grinding and cutting a multilayer body having a hollow structure and dividing it into individual solid state image pickup devices and the like, of a number of chip size package (CSP) type solid state image pickup devices or the like collectively manufactured at a wafer level.

### BACKGROUND ART

Compactness is increasingly demanded of solid state image pickup devices composed of CCD and CMOS, which are used for digital cameras and cellular phones. Therefore, a migration from a conventional large-sized package in which whole solid state image pickup element chips are hermetically sealed in a package of ceramics or the like to a chip size package (CSP) type which is in substantially equal size to that of a solid state image pickup element chip are taking place recently.

In such circumstances, there is provided a solid state image pickup device with a structure in which a sealing member (transparent glass plate) composed of a transparent material with a frame part (spacer) integrally formed at its undersurface edge part is disposed for only a light receiving area of a solid state image pickup element chip, and electrodes (pads) for carrying out wiring from an outside are arranged on an outer side of the frame part (spacer) (for example, see Japanese Patent Application Laid-Open No. 07-202152).

When the solid state image pickup devices described in Japanese Patent Application Laid-Open No. 07-202152 are collectively manufactured at a wafer level, a number of solid state image pickup devices are formed on a wafer (semiconductor substrate), first. Meanwhile, a number of frame parts (spacers) which enclose light receiving areas of the solid state image pickup elements are integrally formed on the sealing member (transparent glass plate) composed of the transparent material.

Next, the sealing member (transparent glass plate) is joined to the wafer via the frame parts (spacers) to seal the light receiving area of each of the solid state image pickup elements to manufacture a multilayer body on which a number of solid state image pickup devices are formed at a wafer level. Next, the multilayer body is divided into the individual solid state image pickup devices, and thereby, the solid state image pickup device described in Japanese Patent Application Laid-Open No. 07-202152 is obtained.

However, in the aforementioned Japanese Patent Application Laid-Open No. 07-202152 describes nothing about a method for dividing the multilayer body on which a number of solid state image pickup devices are formed at a wafer level into the individual solid state image pickup devices.

Besides, there is provided a method for separating the transparent glass plate and the wafer into individual solid state image pickup devices by forming a spacer on a transparent glass plate to correspond to a position enclosing a light receiving part of each of a number of solid state image pickup elements formed on a wafer (semiconductor substrate), forming separation grooves between the adjacent spacers while forming separation grooves between adjacent chips on the wafer, bonding the transparent glass plate to the wafer at the spacer portions to form a gap portion between the transparent glass plate and the wafer, and thereafter, polishing the transparent glass plate and the wafer by chemical mechanical polishing (CMP) until reaching the separation grooves to separate the transparent glass plate and the wafer into the individual solid state image pickup devices. As for width of the separation groove of the transparent glass plate, necessary width for exposing a pad surface formed at an outer side of the light receiving part of the solid state image pickup element to carry out wiring and the like from the outside is taken (for example, see Japanese Patent Application Laid-Open No. 2004-6834).

However, in the art described in Japanese Patent Application Laid-Open No. 2004-6834, a process step of forming the separation grooves in both the transparent glass plate and the wafer is necessary, and further, the transparent glass plate and the wafer are polished by chemical mechanical polishing to decrease the thickness until reaching the separation grooves, thus causing the problem that time taken for separation is long.

### DISCLOSURE OF THE INVENTION

To solve such problems, method of grinding and cutting the transparent glass plate so that the lowest point of a grindstone passes through a gap portion formed between the wafer and the transparent glass plate at a top part of the pad by using a disk-shaped grindstone (dicing blade) having necessary width for exposing a pad surface of the wafer by using a dicing device or the like, for example, is conceivable.

However, in the case of the method for grinding and cutting by using such a grindstone, when the height of the gap portion formed between the wafer and the transparent glass plate is as extremely small as about 100 μm, for example, when a glass broken piece 12A which occurs in the course of grinding and cutting of the transparent glass plate 12 is discharged as shown in FIG. 10A and FIG. 10B showing a A to A′ section of FIG. 10A and a partial enlarged view, it is caught in a space between a grindstone 52 and a wafer 11, stirred up, and dragged in the extreme, whereby a serious problem of damaging the wafer 11 arises.

The present invention is made in view of the above circumstances, and has its object to provide a method of grinding a multilayer body, which can prevent the substrate from being damaged by a broken piece of the planar substance occurring during grinding and cutting, in grinding and cutting the planar substance of a multilayer body constructed by a substrate and the planar substance which are joined to each other having an extremely narrow gap portion, as a solid state image pickup device, for example.

Further, the present invention also has an object to provide a method of grinding a solid state image pickup device group capable of preventing damage to a wafer by a broken piece of the transparent glass plate which occurs during grinding and cutting, in grinding and cutting the transparent glass plate of the solid state image pickup device group constructed by a wafer of the solid state image pickup element and the transparent glass plate which are joined to each other having an extremely narrow gap portion, and a method of manufacturing the solid state image pickup device which is high in yield.

In order to achieve the above described objects, a first aspect of the present invention is a method of grinding a multilayer body for grinding and cutting a planar substance by cutting into a gap portion with a grindstone for the multilayer body in which the planar substance and a substrate are joined via a projected part or a spacer formed on the planar substance, and a gap portion is provided between the aforesaid substrate and the aforesaid planar substance, characterized by comprising forming a protection layer of the aforesaid substrate by disposing a protection material in the aforesaid gap portion in advance, and grinding and cutting the aforesaid planar substance.

According to the first aspect, the protection layer of the substrate is formed in the gap portion in advance before the planar substance is ground and cut, and therefore, the substrate is not damaged by the broken piece which occurs during grinding and cutting of the planar substance even with the extremely narrow gap portion.

A second aspect of the present invention is, in the first aspect, wherein the aforesaid protection layer is formed by filling a fluid material into the aforesaid gap portion. According to the second aspect, the fluid material is filled in the gap portion, and therefore, even with the extremely narrow gap portion, the protection layer can be easily formed.

A third aspect of the present invention is, in the second aspect, characterized in that the aforesaid fluid material is filled in the aforesaid gap portion under a reduced pressure environment. According to the third aspect, the fluid material is filled in the gap portion under the reduced pressure environment, and therefore, even with the extremely narrow gap portion, the fluid material can be easily filled.

A fourth aspect of the present invention is, in the second aspect or the third aspect, characterized in that before the aforesaid grinding, the aforesaid fluid material filled in the aforesaid gap portion is cooled and solidified. According to the fourth aspect, the fluid material is cooled and solidified before grinding, and therefore, it functions as the favorable protection layer, and the substrate is not damaged by the broken piece which occurs during grinding and cutting of the planar substance.

A fifth aspect of the present invention is, in the fourth aspect, the aforesaid grinding is performed under an environment at a temperature of a melting point of the aforesaid fluid material or lower. According to the fifth aspect, grinding is performed under the environment at the temperature of the melting point of the fluid material or lower, and therefore, the solidified fluid material is ground while keeping the solidified state, thus maintaining the function as the protection layer favorably.

A sixth aspect of the present invention is, in the fifth aspect, the aforesaid grinding is performed by placing the aforesaid multilayer body on a table having a cooling function. According to the sixth aspect, the table on which the multilayer body is placed has the cooling function, and therefore, grinding can be performed while the temperature environment at the melting point of the fluid material or lower is maintained.

A seventh aspect of the present invention is, in the fifth aspect or the sixth aspect, characterized in that in the aforesaid grinding, a grinding solution in which an anti-freezing solution is mixed is used. According to the seventh aspect, the anti-freezing solution is mixed in the grinding solution, and therefore, the grinding solution does not freeze under the low temperature environment, thus making it possible to perform favorable grinding.

An eighth aspect of the present invention is, in the second aspect or the third aspect, characterized in that the aforesaid grinding is performed in a state in which the aforesaid multilayer body is soaked in the aforesaid fluid material. According to the eighth aspect, grinding is performed in the state in which the multilayer body is buried in the fluid material, and therefore, the fluid material does not flow out of the gap portion during grinding, thus making it possible to maintain the function as the protection layer.

A ninth aspect of the present invention is, in the first aspect, characterized in that before the aforesaid planar substance is joined to the aforesaid substrate, the aforesaid protection material is coated onto a surface of the aforesaid planer substance on a side where the aforesaid gap portion is formed. According to the ninth aspect, the protection material is previously coated onto the surface of the planar substance at the side where the gap portion is formed before the planar substance is joined to the substrate, and therefore, even with the extremely narrow gap portion, the protection layer can be easily formed.

Besides, in order to achieve the above described object, a method of manufacturing a solid state image pickup device according to a tenth aspect of the present invention comprising a steps of: forming a number of solid state image pickup elements on a surface of a wafer; forming frame-shaped spacers of a predetermined thickness in a shape enclosing the individual solid state image pickup elements, at spots corresponding to the aforesaid solid state image pickup elements on a lower surface of a transparent flat plate which is joined to the aforesaid wafer; forming grooves with predetermined depth between the aforesaid spacers on the lower surface of the aforesaid transparent flat plate; positioning the aforesaid wafer and the aforesaid transparent flat plate and joining them via the aforesaid spacers; performing grinding for the aforesaid transparent flat plate and dividing the transparent flat plate to correspond to the aforesaid individual solid state image pickup elements; and dividing the aforesaid wafer to correspond to the individual solid state image pickup elements.

According to the tenth aspect, the step of forming the groove of the predetermined depth between the aforesaid spacers on the lower surface of the transparent flat plate is included, and therefore, the gap between the grindstone and the wafer surface can be sufficiently taken at the time of grinding and cutting the transparent flat plate. Therefore, the broken pieces of the transparent flat plate occurring by grinding are easily discharged, and damage to the surface of the wafer by the broken pieces is relieved.

An eleventh aspect of the present invention is, in the tenth aspect, characterized in that in the aforesaid step of dividing the aforesaid transparent flat plate, the aforesaid transparent flat plate is ground and cut with a disk-shaped grindstone having a larger thickness dimension than a width dimension of the groove of the aforesaid transparent flat plate.

According to the eleventh aspect, the width of the ground and cut groove is larger than the width of the groove which is previously formed on the transparent flat plate, and therefore, the bearing portion for the disk-shaped grindstone is formed in the transparent flat plate, thus making it difficult for a large broken piece of the transparent flat plate to occur. Therefore, damage to the surface of the wafer is relieved.

A twelfth aspect of the present invention is, in the tenth aspect or the eleventh aspect, characterized in that the aforesaid step of dividing the aforesaid transparent flat plate includes a step of forming a protection layer of the aforesaid wafer by filling a fluid material in a gap portion comprising the groove of the aforesaid transparent flat plate and a space between the aforesaid spacers under the groove.

According to the twelfth aspect, the protection layer of the wafer is formed by filling the fluid material in the gap portion below the ground and cut portion of the transparent flat plate, and therefore, damage to the surface of the wafer by the broken piece of the transparent flat plate occurring by grinding is prevented.

As described above, according to the method of grinding the multilayer body of the present invention, in grinding and cutting the planar substance of the multilayer body in which the planar substance and the substrate are layered with the gap portion provided, grinding and cutting are performed after the protection layer of the substrate is previously formed in the gap portion, and therefore, even with the extremely narrow gap portion, the substrate is not damaged by the broken piece occurring during grinding and cutting of the planar substance.

Besides, according to the method of manufacturing the solid state image pickup device of the present invention, in grinding and cutting the transparent glass plate of the solid state image pickup device group constructed by the solid state image pickup element wafer and the transparent glass plate which are joined with the extremely narrow gap portion therebetween, the height of the gap portion is increased by previously forming the groove in the ground and cut portion of the transparent glass plate. Therefore, the broken pieces of the transparent glass plate occurring during grinding and cutting are easily discharged, damage to the wafer by the broken pieces can be prevented, and the method of manufacturing the solid state image pickup device high in yield can be obtained.

### BRIEF DESCRIPTION OF THE DRAWINGS

FIGS. 1A to 1D are explanatory views showing an assembling process of a solid state image pickup device which is an application target example of a method of grinding a multilayer body according to the present invention;

FIG. 2 is a schematic view of a protection film forming process step explaining an embodiment of the method of grinding a multilayer body according to the present invention;

FIGS. 3A and 3B are schematic views of a grinding and cutting process step explaining the embodiment of the method of grinding a multilayer body according to the present invention;

FIG. 4 is a schematic view of the protection film forming process step explaining another embodiment of the method of grinding a multilayer body according to the present invention;

FIGS. 5A to 5E are schematic views showing an assembling process explaining the embodiment of a method of manufacturing a solid state image pickup device according to the present invention;

FIGS. 6A to 6C are schematic views of a grinding and cutting process step explaining the embodiment of the method of manufacturing the solid state image pickup device according to the present invention;

FIG. 7 is a schematic view of the protection film forming process explaining another embodiment of the method of manufacturing the solid state image pickup device according to the present invention;

FIGS. 8A and 8B are schematic views of a grinding and cutting process step explaining another embodiment of the method of manufacturing the solid state image pickup device according to the present invention;

FIG. 9 is a schematic view explaining grinding and cutting with ultrasonic vibration added to a grinding solution; and

FIGS. 10A and 10B are schematic views explaining conventional grinding and cutting.

### DESCRIPTION OF SYMBOLS

11 . . . wafer (substrate), 11A . . . solid state image pickup element, 12 . . . transparent glass plate (planar substance, transparent flat plate), 12A . . . glass broken piece (broken piece), 12B . . . groove, 13 . . . spacer, 14, 14A . . . gap portion, 15 . . . protection layer, 20 . . . multilayer body, 21 . . . solid state image pickup device, 52 . . . dicing blade (grindstone, disk-shaped grindstone)

### BEST MODE FOR CARRYING OUT THE INVENTION

Hereinafter, a preferred embodiment of a method of grinding a multilayer body and a method of manufacturing a solid state image pickup device according to the present invention will be described in detail with reference to the attached drawings. Note that the same members in each drawing are given the same reference numerals and characters.

First, an embodiment of the method of grinding the multilayer body will be described. In this embodiment, an application example to the manufacturing process of a CSP type solid state image pickup device will be described.

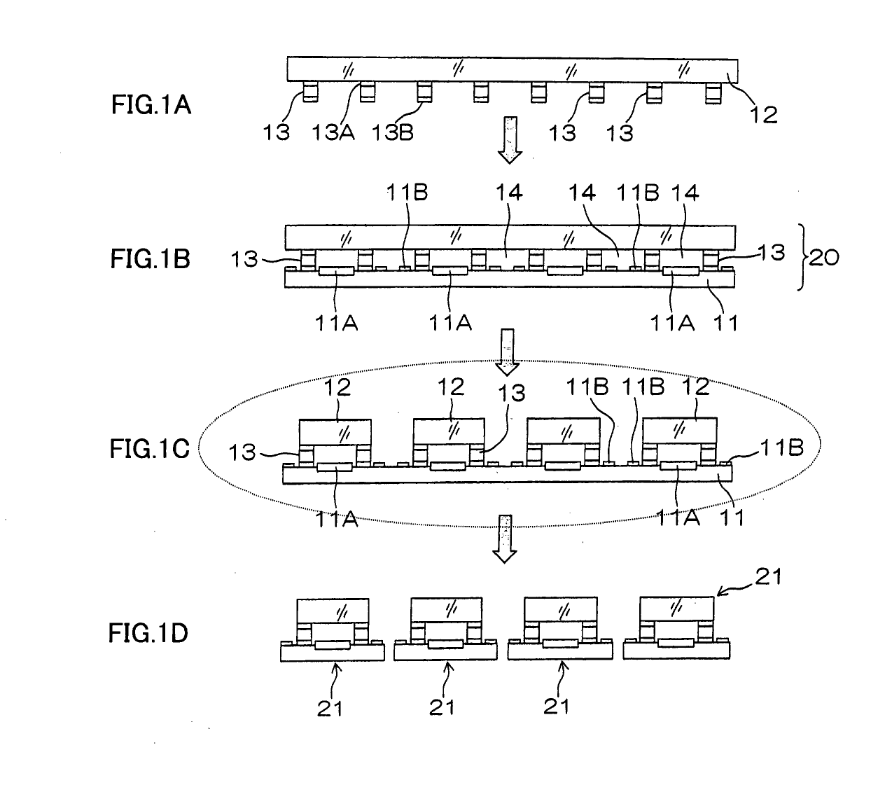

Prior to the explanation, an outline of a manufacturing process of the CSP type solid state image pickup device to which the grinding method of the present invention is applied will be described. FIGS. 1A to 1D are explanatory views showing the manufacturing process of the CSP type solid state image pickup device. As shown in FIG. 1B, a number of solid state image pickup elements 11A are formed on a semiconductor substrate (wafer) 11 (corresponding to a substrate of the present invention).

A general semiconductor element manufacturing process is applied to manufacture of the solid state image pickup element 11A, and the solid state image pickup element 11A has the structure in which microscopic elements constructed by a photodiode that is a light receiving element formed on the wafer 11, a transfer electrode that transfers excitation voltage to an outside, a light shield film having an opening, an interlayer insulation film, an inner lens formed on a top part of the interlayer insulation film, a color filter provided at a top part of the inner lens via an intermediate layer, and a micro lens that is provided at a top part of the color filter via an intermediate layer and the like are arranged in a planar array form.

Since the solid state image pickup element 11A is constructed as described above, light incident thereon from the outside is gathered by the micro lens and the inner lens and irradiated to the photodiode, so that the effective aperture ratio is raised.

Besides, pads 11B, 11B for carrying out wiring to the outside are formed outside the solid state image pickup element 11A as shown in FIG. 1B.

The process shown FIGS. 1A to 1D schematically shows a process of sticking a transparent glass plate 12 (corresponding to a plate-shaped subject) to the wafer 11 on which the aforementioned solid state image pickup elements 11A are formed to seal the light receiving parts of the solid state image pickup elements 11A, and then, dividing the wafer 11 into individual solid state image pickup devices 21.

First, as shown in FIG. 1A, a spacer 13 composed of silicone is formed on the transparent glass plate 12. Formation of the spacer 13 is performed by coating an adhesive 13A to the transparent glass plate 12, to which a silicon plate is bonded. Next, the spacer 13 in a necessary shape is formed by using photolithography and the dry etching technique, and finally, an adhesive 13B is transferred to only a spacer 13 part.

Next, the transparent glass plate 12 provided with the spacers 13 on the whole surface as described above is bonded to the wafer 11 via the spacers 13. Thereby, as shown in FIG. 1B, a multilayer body 20 in which a number of solid state image pickup devices 21 with a structure in which the light receiving parts of the solid state image pickup elements 11A are sealed between the wafer 11 and the transparent glass plate 12 with a gap portion 14 are formed at a wafer level is manufactured.

Next, only the transparent glass plate 12 of the multilayer body 20 is ground and cut by cutting into the gap portion 14 with a grindstone of about 0.6 to 1.2 mm thick to divide the transparent glass plate 12 and expose the pads 11B, 11B on the wafer 11 (FIG. 1C). Next, each portion between the pad 11B and the pad 11B of the wafer 11 is ground and cut with the grindstone to divide the multilayer body 20 into the individual solid state image pickup devices 21 (FIG. 1D).

Since a single crystal silicon wafer is generally used as the wafer 11, and the material of the spacer 13 is desired to be a material similar to the wafer 11 and the transparent glass plate 12 in the physical properties such as thermal expansion coefficient and the like, the material of the spacer 13 is preferably polycrystalline silicon.

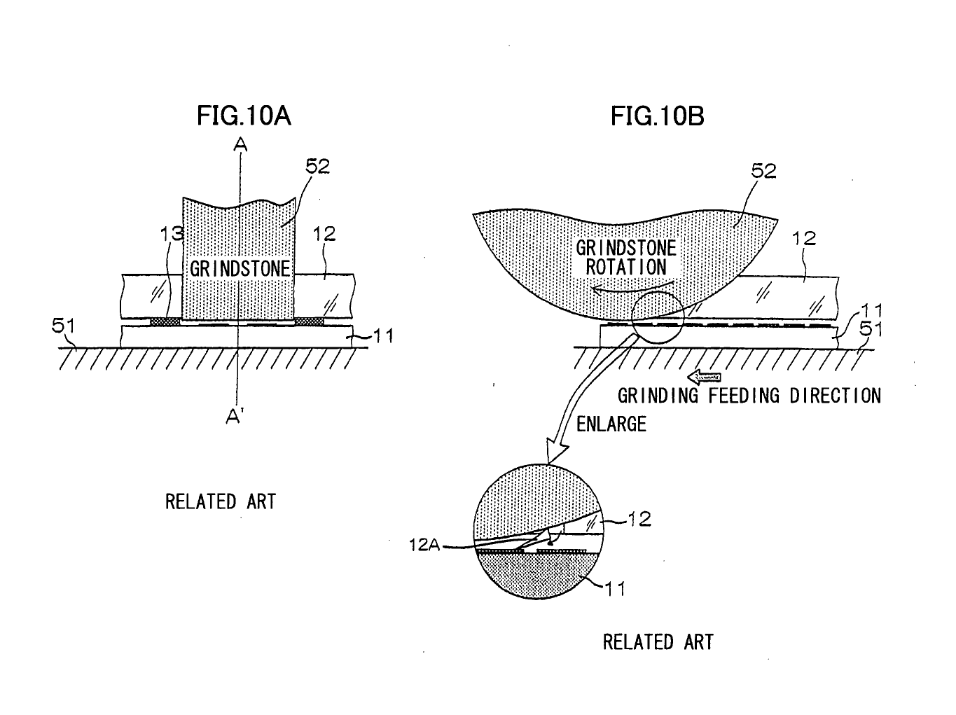

In the grinding and cutting process of the transparent glass plate 12 shown in FIG. 1C, a gap of the gap portion 14 between the wafer 11 and the transparent glass plate 12 is about 100 pm and extremely narrow due to thinning of the solid state image pickup device 21, and therefore, as described in the aforementioned FIGS. 10A and 10B, the glass broken piece 12A occurring during the process of grinding and cutting of the transparent glass plate 12 is caught in the gap between the grindstone 52 and the wafer 11, stirred up or dragged to damage the wafer 11. Therefore, the grinding method of the present invention is favorably used in the grinding and cutting process of the transparent glass plate 12.

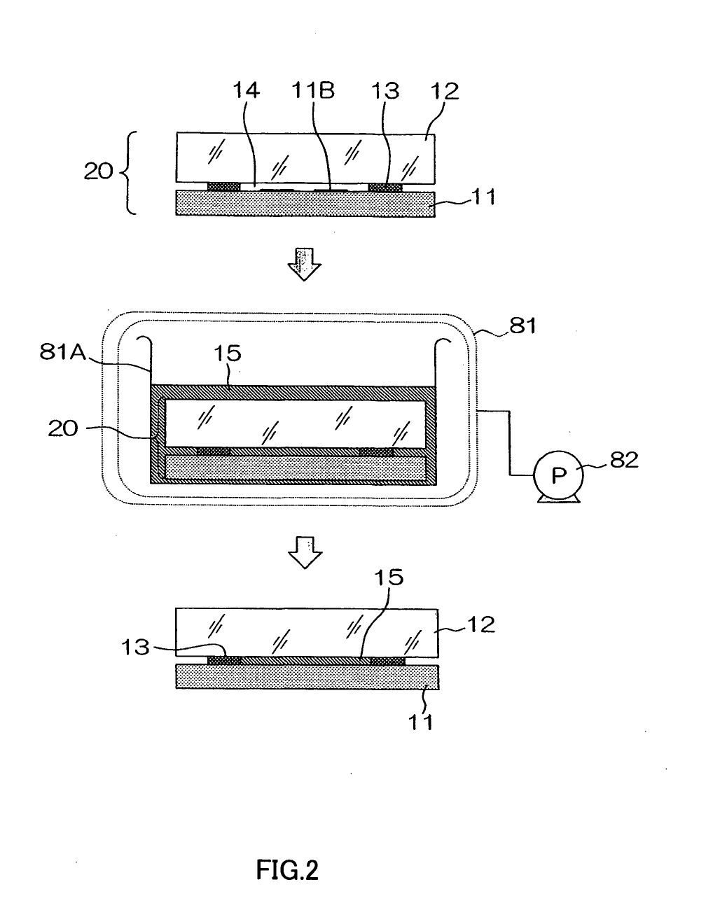

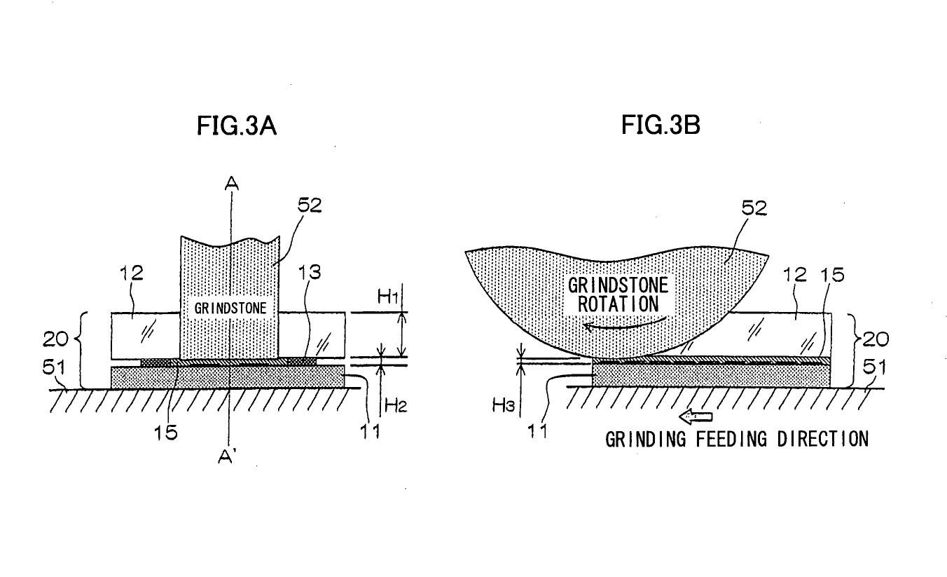

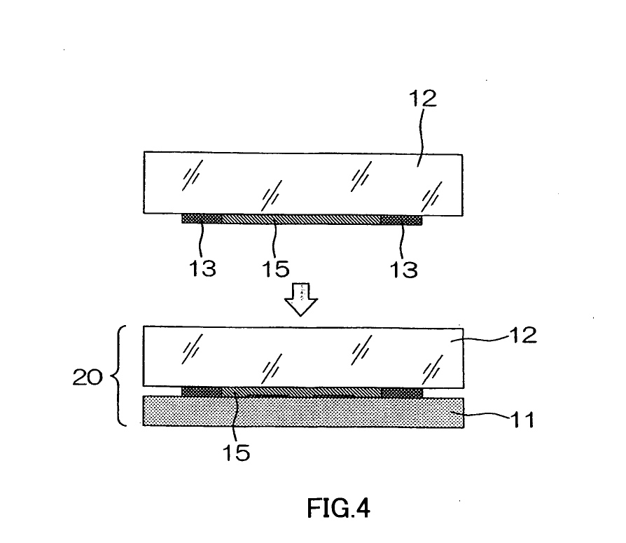

FIG. 2 and FIGS. 3A and 3B are schematic views explaining the present invention. The multilayer bodies 20 in FIG. 2 and FIGS. 3A and 3B are actually manufactured at a wafer level, but in the drawings, only one portion which is ground is illustrated for simplification. The same thing applies in FIG. 4 below.

In the present invention, a fluid material (including gel materials) of a protection layer 15 which protects the wafer 11 is filled into the gap portion 14 of the multilayer body 20. For this purpose, the multilayer body 20 is soaked into a tray 81A filled with the fluid material of the protection layer 15, which is kept inside a vacuum chamber 81 which is decompressed by a vacuum pump 82 for a predetermined time. Thereby, the air inside the gap portion 14 of the multilayer body 20 is discharged and the fluid material of the protection layer 15 is easily filled in the gap portion 14.

Next, as shown in FIGS. 3A and 3B, the multilayer body 20 is fixed on a wafer table 51 of a dicing device, and a lowest end of a blade of a dicing blade (grindstone) 52 is set at a position where it slightly enters the gap portion 14 to grind and cut the transparent glass plate 12. At this time, even if a glass broken piece 12A occurs in the course of grinding and cutting of the transparent glass plate 12, the wafer 11 is not damaged because the protection layer 15 exists in the gap portion 14.

FIG. 3A shows a sectional view in the direction perpendicular to the grinding and cutting direction, and FIG. 3B shows a sectional view taken along the A to A′ line in FIG. 3A.

Next, the wafer 11 portion is fully cut by another thin dicing blade, and finally, a cleaning fluid is injected with a spin cleaner to remove the protection layer 15. Note that the multilayer 20 is ground and cut with a dicing sheet not shown being stuck on a back surface of the wafer 11. Therefore, even if the multilayer body 20 is divided into individual solid state image pickup devices 21, it does not fall to pieces.

Next, examples, in which the protection layer 15 is restrained from being depleted due to rotational force of the dicing blade 52, injection of the grinding solution and the like, and effectively functions as the protection layer of the wafer 11, when grinding and cutting are performed for the multilayer body 20 which is constructed to have the size of the thickness H₁ of the transparent glass plate 12=500 μm, the thickness H₂ of the spacer 13=100 μm with the cut depth of the dicing blade 52 from the top surface of the transparent glass plate 12 being 530 μm (namely, a clearance H₃ between the lowest end of the blade of the dicing blade 52 and the wafer top surface is 70 μm), will be described.

As the common matters in the following examples, the degree of vacuum of the vacuum chamber 81 when the fluid material of the protection layer 15 was filled in the gap portion 14 is about 5 to 80 kPa, and as for the dicing blade 52, the metal bond blade, which was made by bonding the diamond abrasive grain of a grain size of 8 to 40 μm with nickel, and was 100 mm in diameter and 1.0 mm thick, was used. The rotational frequency was set at 4,000 to 6,000 rpm. The feeding speed of the wafer table 51 is set at 0.2 to 1.0 mm/sec.

As for the dicing blade 52, a resin bond blade which is made by bonding diamond abrasive grain with a phenol resin or the like is more active in autogenous action of the abrasive grain and is favorable in cutting performance. However, the resin bond blade wears fast, and in order to ensure the cutting depth, it is necessary to adjust the height frequently. Therefore, the metal bond blade was used in the examples.

### EXAMPLE 1

The multilayer body 20 was soaked in the fluid material which was to be the protection layer 15, and the fluid material was filled in the gap portion 14 by using the vacuum chamber 81. The fluid material which was used was the solution including gelatin or agar, and the material, which is difficult to fluidize even when it is returned to the normal temperature environment once it is cooled and solidified at a low temperature, was used.

After the fluid material was filled in the gap portion 14, the multilayer body 20 was cooled in the refrigerator (about 4 to 8° C.), and the fluid material was solidified into the pudding form and the protection layer 15 was formed.

Next, the multilayer body 20 was set at the dicing device, the transparent glass plate 12 was ground and cut under the room temperature environment, and the pads 11B and 11B were exposed. When the multilayer body 20 after being machined was observed on the monitor screen by using the observation optical system included in the dicing device, a flaw which was large and deep enough to break the circuit wiring was not found, as for the flaw on the surface of the wafer 11 by the glass broken piece 12A, and as for the number of flaws in the size of 10 μm or less, about ten flaws per chip were found, which was within the allowable range.

### EXAMPLE 2

The multilayer body 20 was soaked in the fluid material which was to be the protection layer 15, and the fluid material was filled into the gap portion 14 by using the vacuum chamber 81. The fluid material which was used was water or oil. In machining, the periphery of the wafer table 51 of the dicing device was enclosed by the weir, water or oil was filled inside the weir, and the multilayer body 20 was soaked and fixed therein. Then, the transparent glass plate 12 was ground and cut as it was soaked in the water or the oil under the room temperature environment, and the pads 11 B and 11B were exposed.

When the multilayer body 20 after being machined was observed on the monitor screen, a flaw which was large and deep enough to break the circuit wiring was not found, as to the flaw on the surface of the wafer 11, though one or two flaws exceeding 10 μm in size existed, and the number of flaws in the size of 10 μm or less was about ten per chip, which was within the allowable range.

### EXAMPLE 3

As the fluid material which was to be the protection layer 15, the polymer solution of the silicon oil system which freezes at 10° C. was used, the multilayer body 20 was soaked in the solution, and the fluid material was filled in the gap portion 14 by using the vacuum chamber 81. The multilayer body 20 was stored in the refrigerator (about 0 to 6° C.) in this state, the solution was frozen and solidified, and the protection layer 15 was formed.

The multilayer body 20 was chucked by using the table (the table surface temperature of about 0 to 6° C.) having the cooling function such as the refrigerating chuck table as the wafer table 51 of the dicing device. The multilayer body 20 and its periphery were in the state kept at the melting point of this liquid or lower by supplying the grinding water which was cooled to about 0 to 6° C.

When the multilayer body 20 after being machined was observed on the monitor screen, a flaw which exceeds 10 μm in size was not found as to the flaw on the surface of the wafer 11, and as for the flaw in the size of 10 μm or less, only 2 to 3 flaws were interspersed per chip, which was favorable.

As for the fluid material which was filled, the fluid material which is solidified at the room temperature or lower is favorable, and when the material which is solidified at temperature below zero such as water is used, freezing is prevented even at temperature below zero and the liquid state is kept by mixing ethylene glycol being a non-freezing solution into the grinding water.

### EXAMPLE 4

Unlike the aforementioned examples 1 to 3, in this example, the fluid material to be the protection layer 15 was previously coated on the portion to be the gap portion 14 of the transparent glass plate 12 before the transparent glass plate 12 on which the spacers 13 were formed was bonded to the wafer 11 as shown in FIG. 4, instead of filling the fluid material forming the protection layer 15 into the gap portion 14 inside the vacuum chamber 81.

As for the fluid material in this case, a surface active agent composed of silicon, or a surface protective agent composed of silitect, or a photoresist was used, and the fluid material with high viscosity was adopted. Manual coating may be adopted, but in order to coat a very small amount uniformly, use of a dispenser is preferable.

Thereafter, the transparent glass plate 12 was bonded to the wafer 11, which was made the multilayer body 20, then, the multilayer body 20 was set at the dicing device, the transparent glass plate 12 was ground and cut under the normal temperature environment, and the pads 11B, 11B were exposed.

When the multilayer body 20 after machined was observed on the monitor screen, the flaw which was large and deep enough to break the circuit wiring was not found as to the flaw on the surface of the wafer 11, and the number of flaws 10 μm or less in size was 10 or less per chip, which was sufficiently within the allowable range.

As described above, according to the method of grinding the multilayer body of the present invention, the filler into the gap portion 14 functions as the protection layer 15 of the surface of the wafer 11, and therefore, reduction in damage to the surface of the wafer 11 by the broken glass piece 12A during grinding and cutting was achieved.

Besides, the filler exists under the transparent glass plate 12 to be machined, and thereby, the filler simultaneously performs the function as the supporter for the transparent glass plate 12 at the time of grinding. Therefore, occurrence of the glass broken piece 12A itself is suppressed, which results in the effect of reducing the damage to the surface of the wafer 11.

In the present invention, the material of the protection layer 15 which is filled in the gap portion 14 of the multilayer body 20 is not limited to the material used in the aforementioned examples 1 to 4, but various kinds of materials having the similar physical properties can be applied.

The multilayer body 20 in which the transparent glass plate (planar substance) 12 is joined to the wafer (substrate) 11 via the spacer 13 is described, but the present invention is also extremely effectively applied to the multilayer body 20 in which a projected portion is formed on the transparent glass plate (planar substance) 12 by etching or the like instead of using the spacer 13 and the gap portion 14 is formed by joining the transparent glass plate (planar substance) 12 to the wafer (substrate) 11 with the projected portion, similarly to the multilayer body 20 in which the spacer 13 is interposed.

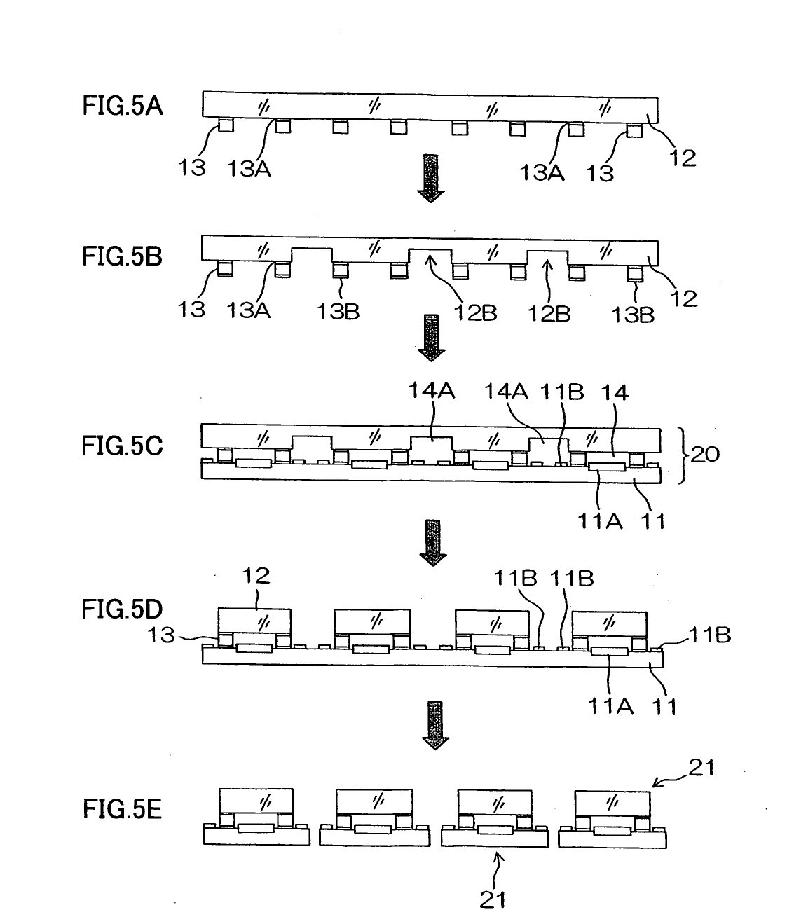

Next, an embodiment of a method of manufacturing a solid state image pickup device according to the present invention will be described. FIGS. 5A to 5E are explanatory views showing the manufacturing process of a CSP type solid state image pickup device. As shown in FIG. 5C, a number of solid state image pickup elements 11A are formed on a semiconductor substrate (wafer) 11.

A general semiconductor element manufacturing process is applied to the manufacture of the solid state image pickup element 11A, and the solid state image pickup element 11A has the structure in which microscopic elements constructed by a photodiode that is a light receiving element formed on the wafer 1, a transfer electrode that transfers excitation voltage to an outside, a light shield film having an opening, an interlayer insulation film, an inner lens formed on a top part of the interlayer insulation film, a color filter provided at a top part of the inner lens via an intermediate layer, a micro lens that is provided at a top part of the color filter via an intermediate layer and the like are arranged in a planar array form.

Since the solid state image pickup element 11A is constructed as described above, light incident thereon from the outside is gathered by the micro lens and the inner lens and irradiated to the photodiode, so that the effective aperture ratio is raised.

Besides, pads 11B, 11B for carrying out wiring to the outside are formed outside the solid state image pickup element 11A as shown in FIG. 5C.

The process shown FIGS. 5A to 5E schematically shows a process of sticking a transparent glass plate 12 (corresponding to a transparent flat plate) to the wafer 11 on which the aforementioned solid state image pickup elements 11A are formed to seal the light receiving parts of the solid state image pickup elements 11A, and then, dividing the wafer 11 and the glass plate 12 into individual solid state image pickup devices 21.

First, as shown in FIG. 5A, spacers 13 composed of silicon which are each in a frame shape enclosing the individual solid state image pickup elements 11A and each have a predetermined thickness are formed on the transparent glass plate 12. Formation of the spacer 13 is performed by coating an adhesive 13A to the transparent glass plate 12, to which a silicon plate is bonded. Next, the spacers 13 each in a necessary shape are formed by using photolithography and the dry etching technique.

Next, as shown in FIG. 5B, a groove 12B is formed between each of the aforementioned frame-shaped spacers 13 and each of the spacers 13. Formation of the groove 12B may be performed by grinding or may be performed by etching. Next, an adhesive 13B is transferred to each of end surface portions of the spacers 13. Note that formation of the grooves 12B may be performed before the silicon plate is bonded to the transparent glass plate 12.

Next, the transparent glass plate 12 provided with the spacers 13 on the whole surface as described above is confronted with the wafer 11, and thereby, positioning is performed with respect to the wafer 11. Positioning is performed by providing alignment marks at the wafer 11 and the transparent glass plate 12 respectively in advance, and by superimposing the alignment mark of the transparent glass plate 12 onto the alignment mark of the wafer 11.

Next, the transparent glass plate 12 positioned with respect to the wafer 11 is bonded to the wafer 11 via the spacers 13 and the adhesives 13B. Thereby, as shown in FIG. 5C, the multilayer body 20 in which a number of solid state image pickup devices 21 each having the structure having the gap portion 14 between the wafer 11 and the transparent glass plate 12, in which the light receiving parts of the solid state image pickup devices 11A are sealed are formed at a wafer level is manufactured.

Note that a space portion in which the groove 12B is formed between the solid state image pickup elements 11A forms a gap portion 14A which is higher than the gap portion 14 by the amount of the groove 12B.

Next, only the transparent glass plate 12 of the multilayer body 20 is ground and cut by cutting into the gap portion 14A with the grindstone about 0.6 to 1.2 mm thick to divide the transparent glass plate 12, and the pads 11B and 11B on the wafer 11 are exposed (FIG. 5D).

Next, each portion between the pads 11B and pads 11B of the wafer 11 is ground and cut with another thin grindstone, and the wafer 11 is divided into the individual image pickup devices 21 (FIG. 5E). Note that the multilayer body 20 is ground and cut with the dicing sheet not shown stuck onto the back surface of the wafer 11. Therefore, even if the multilayer body 20 is divided into the individual solid state image pickup devices 21, it does not fall to pieces.

Since a single crystal silicon wafer is generally used as the wafer 11, the material of the spacer 13 is preferably polycrystalline silicon because the material of the spacer 13 is desired to be the material similar to those of the wafer 11 and the transparent glass plate 12 in the physical properties such as a thermal expansion coefficient and the like.

In the grinding and cutting process of the transparent glass plate 12 shown in FIG. 5D, the height of the gap portion 14 between the wafer 11 and the transparent glass plate 12 is about 100 μm and extremely narrow due to thinning of the solid state image pickup device 21, and therefore, when the grooves 12B are not formed in the transparent glass plate 12, the broken glass piece 12A which occurs in the course of the grinding and cutting of the transparent glass plate 12 is caught in the gap between the grindstone 52 and the wafer 11, stirred up or dragged and damages the wafer 11 side as explained in the aforementioned FIG. 10A and FIG. 10B.

In the present invention, the grooves 12B are formed on the transparent glass plate 12, and the gap portion 14A between the transparent glass plate 12 and the wafer 11 in the ground and cut portion is taken large, and therefore, the glass broken piece 12A is easily discharged and does not damage the wafer 11.

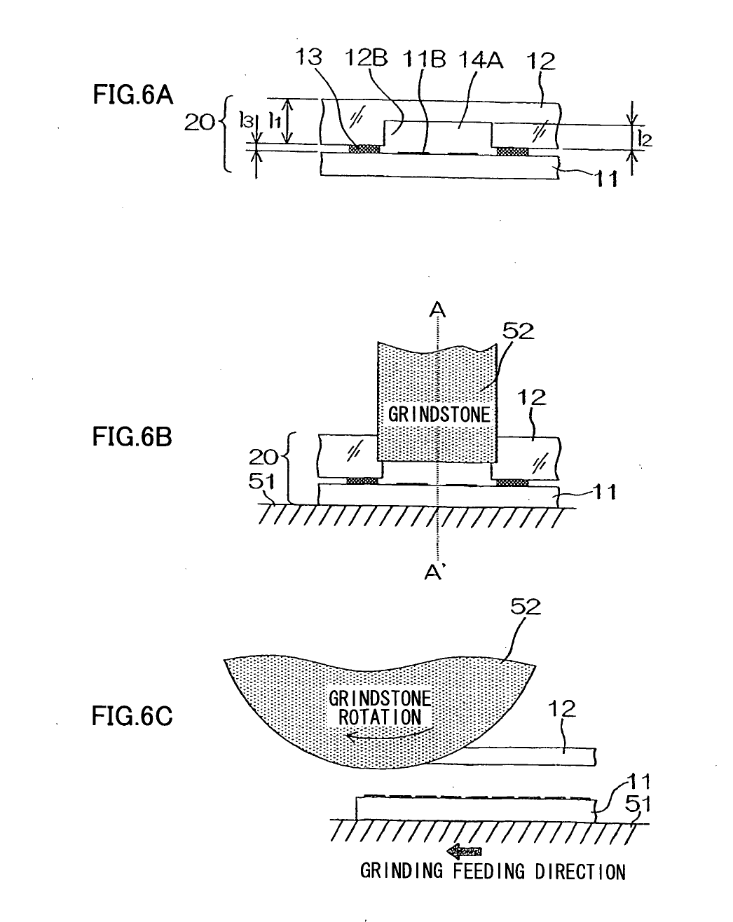

Next, concerning the grinding and cutting of the transparent glass plate 12, a concrete example thereof will be described with reference to FIGS. 6A to 6C. First, the grooves 12B of width of 900 μm and depth l₂=300 μm are previously formed in the transparent glass plate 12 of the thickness l₁=500 μm, and the transparent glass plate 12 is stuck on the wafer 11 via the spacer 13 of the thickness l₃=100 μm, whereby the multilayer body 20 which is a group of the solid state image pickup devices 21 at a wafer level is formed (FIG. 6A).

The multilayer body 20 is sucked and placed on the wafer table 51 of the dicing device, and is set at the position where the lowest point of the blade of the dicing blade (grindstone) 52 enters the gap portion 14A by 50 μm, and the transparent glass plate 12 is ground and cut, whereby the pads 11B and 11B are exposed. Note that FIG. 6B shows a section in the direction perpendicular to the grinding and cutting direction, and FIG. 6C shows the section taken along the line A to A′ in FIG. 6B.

The dicing blade 52 was the metal bond blade made by bonding diamond abrasive grain of the grain size of 8 to 40 μm with nickel, and the metal bond blade with the diameter of 100 mm and the thickness of 1.0 mm was used. The rotational frequency was set at 4,000 to 6,000 rpm. Besides, the feeding speed of the wafer table 51 was set at 0.2 to 1.0 mm/sec.

By grinding and cutting the transparent glass plate 12 by using the dicing blade 52 having larger thickness (1,000 μm) than the width (900 μm) of the groove 12B formed on the transparent glass plate 12, a receiving portion of the dicing blade 52 is formed in the transparent glass plate 12, and receives the grinding resistance, and therefore a large broken piece of the transparent glass plate 12 hardly occurs at the time of grinding and cutting.

Note that as for the dicing blade 52, a resin bond blade made by bonding the diamond abrasive grain with a phenol resin or the like is more active in the autogenous action and is favorable in cutting performance. However, it wears fast, and in order to secure the cutting depth, it is necessary to frequently perform height adjustment, and therefore, the metal bond blade was used in the example.

When the multilayer body 20 after machined was observed with the monitor screen by using the observation optical system included in the dicing device, a flaw which was large and deep enough to break the circuit wiring was not found, though one or two flaws exceeding 10 μm in size were interspersed in each chip as to the flaw on the surface of the wafer 11, and the number of flaws 10 μm or less in size is about 20 to 30 per chip, which was within the allowable range.

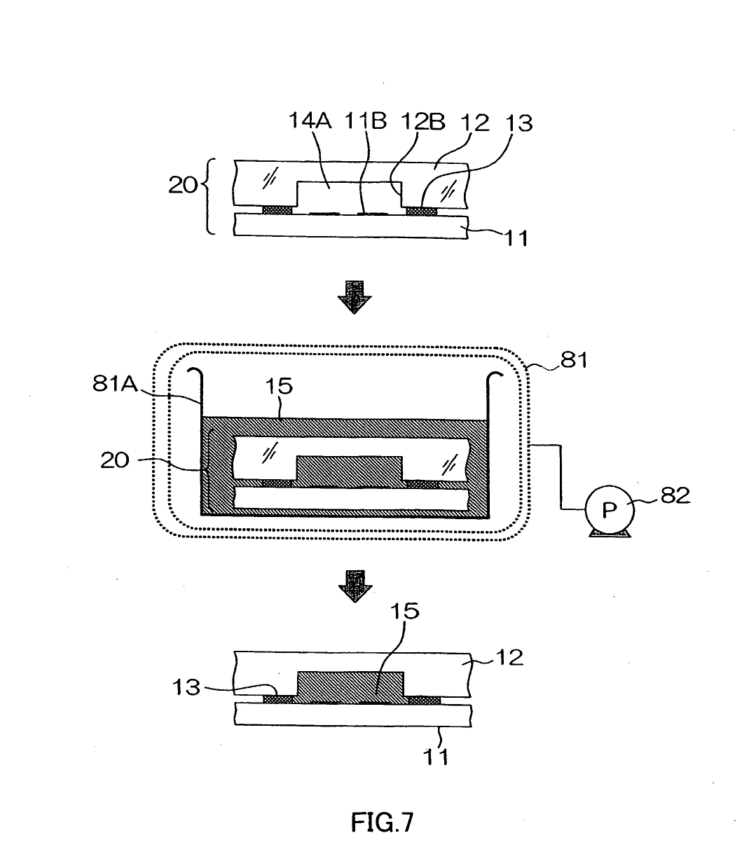

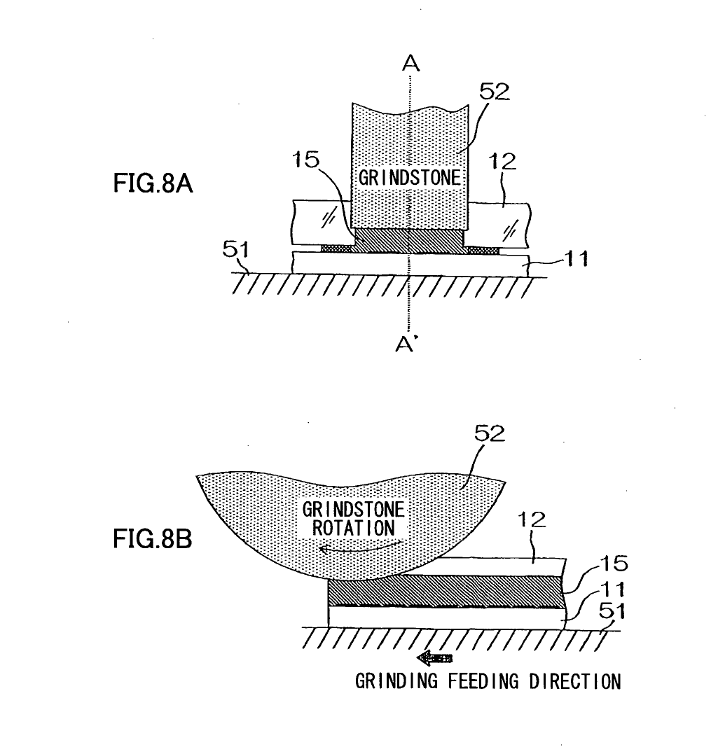

Next, another embodiment of the method of manufacturing the solid state image pickup device of the present invention will be described with reference to FIG. 7 and FIGS. 8A and 8B. In this embodiment, a process of forming a protection layer of the surface of the wafer 11 in the gap portion 14A is added to the aforementioned embodiment. Note that the multilayer body 20 in FIG. 7 is actually manufactured at a wafer level, but in the drawing, only one ground portion is illustrated for simplification.

First, as shown in FIG. 7, a fluid material (including a gelatinous material) of the protection layer 15 for protecting the wafer 11 is filled in the gap portion 14A of the multilayer body 20 in which the groove 12B is formed in the transparent glass plate 12. For this purpose, the multilayer body 20 is placed in the tray 81A filled with the fluid material of the protection layer 15, which is kept inside the vacuum chamber 81 decompressed with the vacuum pump 82 for a predetermined time. As a result, air inside the gap portion 14A of the multilayer body 20 is discharged, and the fluid material of the protection layer 15 is easily filled into the gap portion 14A.

Next, as shown in FIGS. 8A and 8B, the multilayer body 20 is fixed on the wafer table 51 of the dicing device and is set at the position where the lowest point of the blade of the dicing blade (grindstone) 52 slightly enters the gap portion 14A to grind and cut the transparent glass plate 12. Even if the broken glass piece 12A occurs at this time while grinding and cutting of the transparent glass plate 12 are under way, the wafer 11 is not damaged because the gap of the gap portion 14A is large and the protection layer 15 exists in the gap portion 14A.

FIG. 8A shows a section in the direction perpendicular to the grinding and cutting direction, and FIG. 8B shows a section taken along the A to A′ line in FIG. 8A.

Next, the wafer 11 portion is fully cut with another thin dicing blade, and finally, the protection layer 15 is removed by injecting a cleaning fluid with the spin cleaner.

Next, a concrete example of grinding and cutting of the transparent glass plate 12 in this other embodiment will be described. The multilayer body 20 was soaked in the fluid material to be the protection layer 15, and the fluid material was filled in the gap portion 14A by using the vacuum chamber 81. The used fluid material was water or oil. The degree of vacuum of the vacuum chamber 81 at the time of filling was set at about 5 to 80 kPa.

The dicing blade 52 was the metal bond blade made by bonding the diamond abrasive grain of the grain size of 8 to 40 μm with nickel, and the metal bond blade with the diameter of 100 mm and thickness of 1.0 mm was used. The rotational frequency of the metal bond blade was set at 4,000 to 6,000 rpm. The feeding speed of the wafer table 51 was set at 0.2 to 1.0 mm/sec.

In machining, the periphery of the wafer table 51 of the dicing device was surrounded with the weir and water or oil was filled therein. The multilayer body 20 was soaked and fixed therein, and the transparent glass plate 12 was ground and cut while it was kept soaked under the room temperature environment, whereby the pads 11B, 11B were exposed.

When the multilayer body 20 after machining was observed on the monitor screen, as to the flaw on the surface of the wafer 11 by the glass broken piece 12A, a flaw which is large and deep enough to break the circuit wiring was not found, and the number of flaws which were 10 μm or less in size was 10 or less per chip, which was within the allowable range.

Note that the fluid material which is solidified at a temperature at the room temperature or lower can be filled in the gap portion 14A of the multilayer body 20, the multilayer body 20 can be stored in the refrigerator in this state and the fluid material can be solidified to form the protection layer 15. The transparent glass plate 12 is ground and cut in this state. In this case, the grinding water is used by decreasing the temperature of the grinding water to the melting point of the filled and solidified material or lower.

For example, when a polymer solution of a silicon oil system which freezes at 10° C. is used as the fluid material which is solidified at the temperature of the room temperature or lower, the solution is filled into the gap portion 14A of the multilayer body 20, after which, the multilayer body 20 is stored in the refrigerator (about 0 to 6° C.) to freeze and solidify the solution. In this case, the multilayer body 20 is chucked by using a table (table surface temperature of about 0 to 6° C.) having a cooling function such as a freezing chuck table as the wafer table 51 of the dicing device.

Besides, the multilayer body 20 and the solution in its periphery are kept at the melting point of the solution or lower by supplying the grinding water cooled to about 0 to 6° C., and the transparent glass plate 12 is ground and cut in this state.

Note that when the fluid material which is solidified at the temperature below zero such as water is used as the fluid material to be filled, freezing is prevented even at a temperature below zero and liquid state is kept, by mixing ethylene glycol which is an antifreeze solution into the grinding water.

Besides, as the fluid material to be the protection layer 15, a material which is a solution including gelatin, agar or the like and is difficult to fluidize even when it is returned to the room temperature environment once it is cooled and solidified at a low temperature is used as the fluid material to be the protection layer 15, and after the fluid material is filled into the gap portion 14A, the multilayer body 20 is cooled in the refrigerator (about 4 to 8° C.), whereby the fluid material is solidified into the pudding form and the protection layer 15 can be formed.

In any case, the fluid material is filled into the gap portion 14A to form the protection layer 15 in addition to the fact that the height of the gap portion 14A is increased by the groove 12B, and therefore, even if the glass broken piece 12A occurs in the course of grinding and cutting of the transparent glass plate 12, it is easily discharged, thus suppressing damage to the wafer 11.

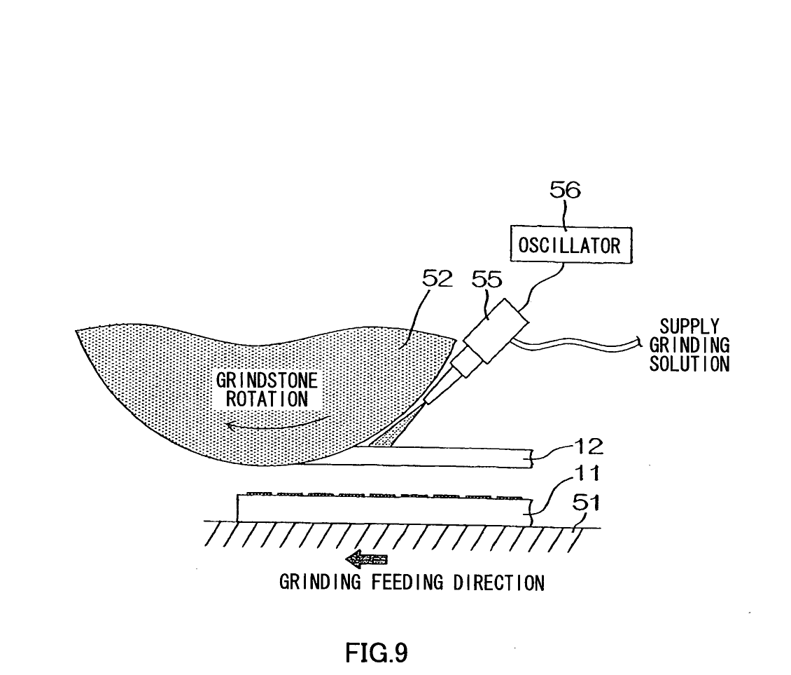

Besides, in grinding and cutting the transparent glass plate 12, grinding and cutting are performed while a grinding solution to which ultrasonic vibration is added is supplied from a grinding solution nozzle 55 with a ultrasonic vibrator as shown in FIG. 9, whereby the vibration is transmitted to the broken glass piece 12A itself and the glass broken piece 12A is smoothly discharged. Therefore, damage to the surface of the wafer 11 by the broken glass piece 12A is further relieved.

As an example in this case, as the oscillator, for example, Model: MSG-331 or the like made by Megasonic Systems Ltd. is used, and the oscillation frequency of the oscillator 56 is preferably about 1.5 to 3.0 MHz, and the ultrasonic power is preferably about 10 to 40 W.

Besides, the ultrasonic energy is the most effectively added to the grinding solution immediately before the discharge from the grinding solution nozzle, and therefore, it is suitable that the ultrasonic vibrator of the grinding solution nozzle 55 with the ultrasonic vibrator is incorporated in a portion as near the tip end of the nozzle as possible.

### INDUSTRIAL APPLICABILITY

As described above, according to the method of manufacturing the solid state image pickup device of the present invention, in grinding and cutting the transparent glass plate of the solid state image pickup device group constructed by the solid state image pickup element wafer and the transparent glass plate which are joined with the extremely narrow gap portion of about 100 μm, the height of the gap portion of the ground and cut region is increased by previously forming the grooves in the transparent glass plate, and therefore, damage to the wafer by the broken piece of the transparent glass plate occurring during grinding and cutting can be prevented, thus making it possible to obtain the method of manufacturing the solid state image pickup device enhanced in yield.

1. A method of grinding a multilayer body for grinding and cutting a planar substance by cutting into a gap portion with a grindstone for the multilayer body in which the planar substance and a substrate are joined via a projected part or a spacer formed on said planar substance, and a gap portion is provided between said substrate and said planar substance, comprising a step of:
forming a protection layer of said substrate by disposing a protection material in said gap portion in advance, and grinding and cutting said planar substance.

2. The method of grinding a multilayer body according to claim 1, wherein said protection layer is formed by filling a fluid material into said gap portion.

3. The method of grinding a multilayer body according to claim 2, wherein said fluid material is filled in said gap portion under a reduced pressure environment.

4. The method of grinding a multilayer body according claim 2, wherein before said grinding, said fluid material filled in said gap portion is cooled and solidified.

5. The method of grinding a multilayer body according to claim 4, wherein said grinding is performed under an environment at a temperature of a melting point of said fluid material or lower.

6. The method of grinding a multilayer body according to claim 6, wherein said grinding is performed by placing said multilayer body on a table having a cooling function.

7. The method of grinding a multilayer body according to claim 6, wherein
in said grinding, a grinding solution in which an anti-freezing solution is mixed is used.

8. The method of grinding a multilayer body according to claim 2, wherein said grinding is performed in a state in which said multilayer body is soaked in said fluid material.

9. The method of grinding a multilayer body according to claim 1, wherein before said planar substance is joined to said substrate, said protection material is coated onto a surface of said planer substance on a side where said gap portion is formed.

10. A method of manufacturing a solid state image pickup device, comprising the steps of:
forming a number of solid state image pickup elements on a surface of a wafer;
forming frame-shaped spacers of a predetermined thickness in a shape enclosing the individual solid state image pickup elements, at spots corresponding to said solid state image pickup elements on a lower surface of a transparent flat plate which is joined to said wafer;
forming grooves with predetermined depth between said spacers on the lower surface of said transparent flat plate;
positioning said wafer and said transparent flat plate and joining them via said spacers;
performing grinding for said transparent flat plate and dividing the transparent flat plate to correspond to said individual solid state image pickup elements; and
dividing said wafer to correspond to the individual solid state image pickup elements.

11. The method of manufacturing a solid state image pickup device according to claim 17, wherein
in said step of dividing said transparent flat plate, said transparent flat plate is ground and cut with a disk-shaped grindstone having a larger thickness dimension than a width dimension of the groove of said transparent flat plate.

12. The method of manufacturing a solid state image pickup device according to claim 17, wherein
said step of dividing said transparent flat plate includes a step of forming a protection layer of said wafer by filling a fluid material in a gap portion comprising the groove of said transparent flat plate and a space between said spacers under the groove.

13. The method of grinding a multilayer body according claim 3, wherein
before said grinding, said fluid material filled in said gap portion is cooled and solidified.

14. The method of grinding a multilayer body according to claim 5, wherein
said grinding is performed under an environment at a temperature of a melting point of said fluid material or lower.

15. The method of grinding multilayer body according to claim 7, wherein
said grinding Is performed by placing said multilayer body on a table having a cooling function.

16. The method of grinding a multilayer body according to claim 7, wherein
in said grinding, a grinding solution in which an anti-freezing solution is mixed is used.

17. The method of grinding a multilayer body according to claim 8, wherein
in said grinding, a grinding solution in which an anti-freezing solution is mixed is used.

18. The method of grinding a multilayer body according to claim 9, wherein
in said grinding, a grinding solution in which an anti-freezing solution is mixed is used.

19. The method of grinding a multilayer body according to claim 3, wherein
said grinding is performed in a state in which said multilayer body is soaked in said fluid material.

20. The method of manufacturing a solid state image pickup device according to claim 18, wherein
said step of dividing said transparent flat plate includes a step of forming a protection layer of said wafer by filling a fluid material in a gap portion comprising the groove of said transparent flat plate and a space between said spacers under the groove.
